(19) United States
(12) Patent Application Publication
(10) Pub. No.: US 2025/0393445 A1
(43) Pub. Date: Dec. 25, 2025

(54) DISPLAY PANEL AND DISPLAY DEVICE

(71) Applicant: HKC CORPORATION LIMITED, SHENZHEN (CN)

(72) Inventors: Yangling TANG, SHENZHEN (CN); Zhisheng XIE, SHENZHEN (CN); Zhi YANG, SHENZHEN (CN); Xiufeng ZHOU, SHENZHEN (CN); Pei XU, SHENZHEN (CN)

(73) Assignee: HKC CORPORATION LIMITED, SHENZHEN (CN)

(21) Appl. No.: 19/243,483

(22) Filed: Jun. 19, 2025

(30) Foreign Application Priority Data
Jun. 21, 2024 (CN) 202410816957.7

(51) Int. Cl. H10K 59/80; H10K 59/131

(52) U.S. Cl. CPC H10K 59/873; H10K 59/131

(57) ABSTRACT

A display panel and a display device are provided. The display panel has a display region and a border region, the border region includes a signal connection region and an isolation dam region disposed sequentially in a direction away from the display region. The signal connection region is at a safety distance from the isolation dam region. The conductive insolation structure is electrically coupled to a cathode, the connecting electrode is electrically coupled to a power line, and the encapsulation layer includes an organic encapsulation layer. The conductive insolation structure protrudes from the connection defining layer, contacts and is conductively connected with the connecting electrode via a plurality of connecting openings. The conductive insolation structure is in the shape of a mesh and defines a plurality of encapsulation openings. The organic encapsulation layer is filled in the plurality of encapsulation openings and covers the conductive insolation structure.

### CROSS-REFERENCE TO RELATED APPLICATIONS

This application claims priority to Chinese Patent Application No. 202410816957.7, filed on Jun. 21, 2024 in the National Intellectual Property Administration of China, the contents of which are herein incorporated by reference in their entireties.

### TECHNICAL FIELD

Embodiments of the present disclosure relate to the field of display technologies, and in particular to a display panel and a display device.

### BACKGROUND

With the continuous development of display technology, for a process route involving a maskless conductive overhang structure (i.e., without using masks), the conductive overhang structure needs to be disposed on a pixel defining layer and configured for evaporation of film layers between pixels and for formation of independent encapsulation between the pixels.

However, if a border (also called as border) encapsulation region directly adopts an encapsulation scheme based on traditional Fine Metal Mask (FMM), the conductive overhang structure may cover a connecting electrode with the entire surface thereof. The conductive overhang structure is connected to the connecting electrode through a via, and may be further connected to a peripheral power line through the connecting electrode. This encapsulation scheme will require an excessive leveling distance of planarization distance for the organic encapsulation layer in the border region, thereby increasing the width of the border.

### SUMMARY

Some embodiments of the present disclosure may provide a display panel and a display device.

A first technical solution provided by some embodiments of the present disclosure is to provide a display panel. The display panel has a display region and a border region located around the display region, the border region includes a signal connection region and an isolation dam region disposed sequentially in a direction away from the display region. The signal connection region is at a safety distance from the isolation dam region.

In a direction substantially perpendicular to the display panel, the signal connection region includes a driving substrate, a connecting electrode, a connection defining layer, a first conductive insolation structure, and an encapsulation layer sequentially stacked on one another. The first conductive insolation structure is electrically coupled to a cathode in the display region, the connecting electrode is electrically coupled to a power line in the driving substrate, and the encapsulation layer includes an organic encapsulation layer.

The first conductive insolation structure protrudes from the connection defining layer, is in the shape of a mesh, and defines a plurality of encapsulation openings; the connection defining layer defines a plurality of connecting openings, the plurality of connecting openings are configured to expose the connecting electrode; an orthographic projection of each of the plurality of connecting openings onto the driving substrate is located within an orthographic projection of the first conductive insolation structure onto the driving substrate, the first conductive insolation structure contacts and is conductively connected with the connecting electrode, and the organic encapsulation layer is filled in the plurality of encapsulation openings and covers the first conductive insolation structure.

A second technical solution provided by some embodiments of the present disclosure is to provide a display device. The display device includes the display panel as previously mentioned. The display device further includes a power supply configured to supply power to the display panel.

A third technical solution provided by some embodiments of the present disclosure is to provide a display panel. The display panel has a display region and a border region located around the display region, the border region includes a signal connection region and an isolation dam region disposed sequentially in a direction away from the display region. The signal connection region is at a safety distance from the isolation dam region. In a direction substantially perpendicular to the display panel, the signal connection region includes a driving substrate, a connecting electrode, a connection defining layer, a first conductive insolation structure, and an encapsulation layer sequentially stacked on one another. The first conductive insolation structure is electrically coupled to a cathode in the display region, the connecting electrode is electrically coupled to a power line in the driving substrate, and the encapsulation layer includes an organic encapsulation layer. The connection defining layer is in the shape of a grid and defines a plurality of connecting openings, the plurality of connecting openings are configured to expose the connecting electrode. An end of the conductive insolation structure is received in the plurality of connecting openings and is electrically connected to the connecting electrode, another end of the conductive insolation structure protrudes out of the plurality of connecting openings such that the conductive insolation structure is formed into a grid with a plurality of encapsulation openings. The organic encapsulation layer is filled in the encapsulation openings, and the conductive insolation structure is configured to block the organic encapsulation layer.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below may be merely some embodiments of the present disclosure, and those skills in the art may obtain other drawings based on the following drawings without creative work.

FIG. 1 is a schematic planar view of a display panel provided by a technical solution of some embodiments of the present disclosure.

FIG. 2 is a schematic cross-sectional view of the display panel in an A-A orientation in some embodiments shown in FIG. 1.

FIG. 3 is a schematic planar view of a region A in some embodiments shown in FIG. 2.

FIG. 4 is a schematic planar view of a display panel provided in some embodiments of the present disclosure.

FIG. 5 is a schematic partial planar view of a region B in some embodiments shown in FIG. 4.

FIG. 6 is a schematic cross-sectional view of the display panel in a B-B orientation in some embodiments shown in FIG. 5.

FIG. 7 is a schematic planar view of a display panel provided in some embodiments of the present disclosure.

FIG. 8 is a schematic planar view of a display panel provided in some embodiments of the present disclosure.

FIG. 9 is a schematic cross-sectional view of the display panel in a C-C orientation in some embodiments shown in FIG. 8.

FIG. 10 is a schematic cross-sectional view of an isolation dam region provided by some embodiments of the present disclosure.

FIG. 11 is a schematic structural view of a display device provided by some embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies may be presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments may be only part of the embodiments of the present disclosure and not all embodiments. Based on the embodiments of the present disclosure, all other embodiments obtained by those skills in the art without any creative work fall within the scope of the present disclosure.

The terms “first”, “second”, and “third” in some embodiments of the present disclosure may be merely used for descriptive purposes and should not be construed as indicating or implying relative importance or implicitly indicating the quantity of the indicated technical features. Thus, the features limited by “first” “second” and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure may be only used to explain the relative positional relationships, motion situations, etc. among the components under a specific posture (as shown in the figures). When the specific posture changes, the directional indications shall be changed accordingly. Furthermore, the terms “including” and “having” and any variations thereof, may be intended to cover non-exclusive inclusion. For example, a process, method, system, product, or device that may include a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification may be not necessarily all referring to the same embodiment, nor may be they mutually exclusive alternative embodiments. It is explicitly and implicitly understood by those skills in the art that the embodiments described herein may be combined with other embodiments.

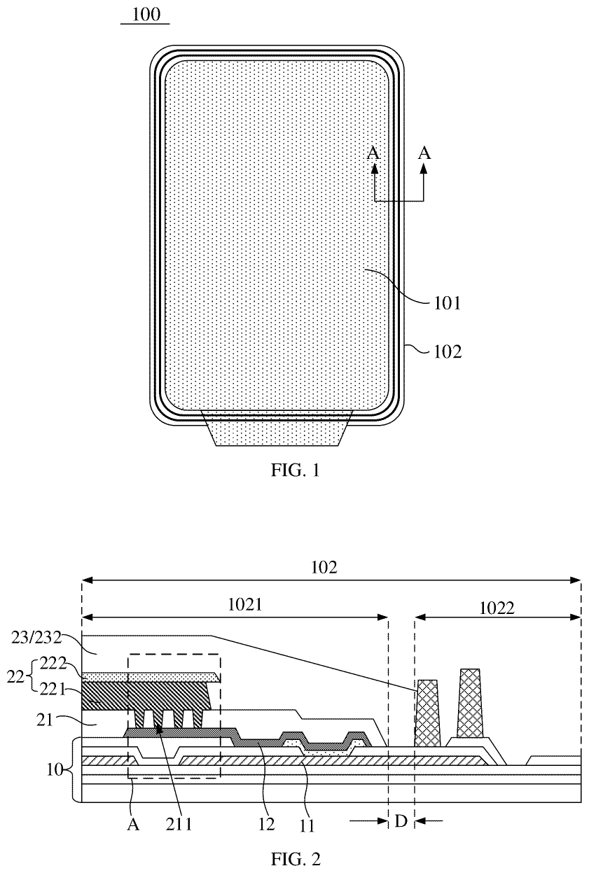

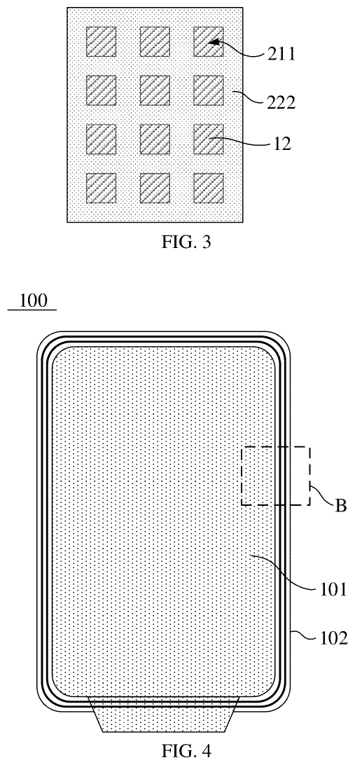

FIG. 1 is a schematic planar view of a display panel provided by a technical solution of some embodiments of the present disclosure, FIG. 2 is a schematic cross-sectional view of the display panel 100 in an A-A orientation in some embodiments shown in FIG. 1, and FIG. 3 is a schematic planar view of a region A in some embodiments shown in FIG. 2. As shown in FIGS. 1-3, in some embodiments, a display panel 100 is provided. The display panel 100 may have a display region 101 and a border region 102 disposed around or surrounding the display region 101. The border region 102 may have a signal connection region 1021 and an isolation dam region 1022 disposed sequentially in a direction away from the display region 101. In some embodiments, a safety distance D may be reserved between the signal connection region 1021 and the isolation dam region 1022. The safety distance D may be configured to reserve a leveling region for leveling of an organic encapsulation layer 232, such that the risk of overflow of the organic encapsulation layer 232 may be reduced.

In some embodiments, as shown in FIG. 2, in a direction substantially perpendicular to the display panel 100, the signal connection region 1021 may include a driving substrate 10, a connecting electrode 12, a pixel defining layer 21, a conductive insolation structure 22, and an encapsulation layer 23 sequentially stacked on one another. In some embodiments, the pixel defining layer 21 may be disposed on a side of the connecting electrode 12 away from the driving substrate 10. The pixel defining layer 21 may cover the connecting electrode 12. The conductive insolation structure 22 may include a conductive structure 221 disposed on the pixel defining layer 21 and a roof structure 222 disposed on the conductive structure 221. An orthographic projection of the conductive structure 221 onto the driving substrate 10 may be at least partially overlapped with an orthographic projection of the connecting electrode 12 onto the driving substrate 10. A plurality of conductive vias 211 may be defined in a part of the pixel defining layer 21 that is located in the overlapping region. The conductive structure 221 may be connected to the connecting electrode 12 through the plurality of conductive vias 211. A power line 11 may be disposed on the driving substrate 10. The connecting electrode 12 may be electrically connected to the power line 11 on the driving substrate 10 through another vias. The conductive structure 221 may be electrically coupled to cathodes in the display region 101, thereby achieving a signal connection between the cathodes in the display region 101 and a signal line, i.e., the power line 11.

In some embodiments, the encapsulation layer 23 may include the organic encapsulation layer 232. The organic encapsulation layer 232 may be arranged on a side of the roof structure 222 away from the driving substrate 10 and further extend to the isolation dam region 1022 in a direction away from the display region 101. However, this encapsulation method causes the organic encapsulation layer 232 to flow directly over the roof structure 222 of the conductive insolation structure 22 and further flow to the isolation dam region 1022. In this case, the organic encapsulation layer 232 may require an over-large or excessive flow leveling distance, and the safety distance D that needs to be reserved may be relatively large, thereby increasing the width of the border.

In the display panel 100 provided by some embodiments of the present disclosure, by changing the connection method between the conductive insolation structure 22 and the connecting electrode 12 in the signal connection region 1021, the conductive insolation structure 22 may offer a function of blocking the organic encapsulation layer 232, such that the leveling distance of the organic encapsulation layer 232 may be effectively shortened, the safety distance D may be reduced, and the width W of the border of the display panel 100 may be effectively reduced.

The present disclosure may be described in detail below with reference to the accompanying drawings and embodiments.

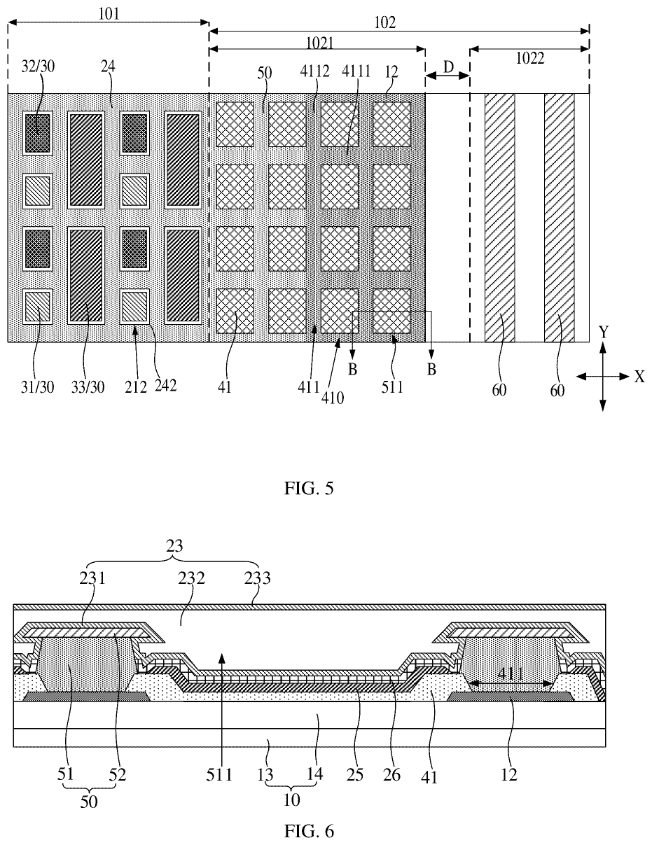

As shown in FIGS. 4-6, FIG. 4 is a schematic planar view of a display panel 100 provided in some embodiments of the present disclosure, FIG. 5 is a schematic partial planar view of a region B in some embodiments shown in FIG. 4, and FIG. 6 is a schematic cross-sectional view of the display panel in a B-B orientation in some embodiments shown in FIG. 5. As shown in FIGS. 4-6, in some embodiments, a display panel 100 is provided. The display panel 100 may have the display region 101 and the border region 102 disposed around or surrounding the display region 101.

In some embodiments, the display panel 100 may include the driving substrate 10. The driving substrate 10 may be divided into the display region 101 and the border region 102 disposed around the display region 101. As shown in FIG. 5, the display region 101 may be configured to display an image. A mesh-like or grid-like pixel defining layer (covered and not shown in FIG. 5) may be arranged in the display region 101. The pixel defining layer may define a plurality of pixel openings 212. The plurality of pixel openings 212 may be configured to separate a plurality of sub-pixel units 30 from each other, such that the problem of pixel light crosstalk may be mitigated. The plurality of pixel openings 212 may be arranged in an array. Besides, a mesh-like first conductive insolation structure 24 may protrude from the pixel defining layer. The first conductive insolation structure 24 may have a plurality of cathode openings 242. The plurality of cathode openings 242 may correspond to the plurality of pixel openings 212 in a one-to-one correspondence. An orthographic projection of each pixel opening 212 onto the driving substrate 10 may be located within an orthographic projection of the corresponding cathode opening 242 onto the driving substrate 10, i.e., each cathode opening 242 may be slightly greater than the corresponding pixel opening 212 and surround the corresponding pixel opening 212. The first conductive insolation structure 24 may be used to replace a mask plate (FMM), and configured to evaporate film layers such as a light emitting layer, a cathode, etc., to form the plurality of sub-pixel units 30. The conductive insolation structure 24 may also be configured to connect the cathodes of the plurality of sub-pixel units 30. In some embodiments, each sub-pixel unit 30 may be arranged in a corresponding pixel opening 212. Each sub-pixel unit 30 may include an anode, a light emitting layer, and a cathode (not shown in the figures) sequentially stacked in a direction away from the driving substrate 10. In some embodiments, for each sub-pixel unit 30, the cathode may extend in the corresponding pixel opening 212 and further extend to the corresponding cathode opening 242, where the cathode contacts the first conductive insolation structure 24 and is conductively connected with the first conductive insolation structure 24. This enables the cathodes of the plurality of sub-pixel units 30 to be electrically or conductively connected to each other through the first conductive insolation structure 24, thereby forming a full-surface mesh-like connection of the cathodes, and thus it is possible to achieve uniform signal distribution across the entire surface of the cathodes. In some embodiments, the sub-pixel units 30 may include a first sub-pixel unit 31, a second sub-pixel unit 32, and a third sub-pixel unit 33 with different light-emitting colors. The light-emitting colors may be red, green, and blue, respectively, in order to achieve a full-color display of the image. In some embodiments, the sub-pixel units 30 may also include a fourth sub-pixel unit with a white light-emitting color, such that a display brightness of the pixel unit may be enhanced, colors of different saturations may be rendered, and a color gamut range may be expanded.

In some embodiments, the border region 102 may have the signal connection region 1021 and the isolation dam region 1022 disposed sequentially in the direction away from the display region 101. In some embodiments, the safety distance D may be reserved between the signal connection region 1021 and the isolation dam region 1022. The safety distance D may be configured to reserve a leveling space for leveling of the organic encapsulation layer 232, such that the risk of overflow of the organic encapsulation layer 232 to the border region 102 may be reduced.

In some embodiments, as shown in FIG. 6, in a direction substantially perpendicular to the display panel 100, the signal connection region 1021 may include the driving substrate 10, the connecting electrode 12, a connection defining layer 41, a second conductive insolation structure 50, and the encapsulation layer 23. The driving substrate 10, the connecting electrode 12, the connection defining layer 41, the second conductive insolation structure 50, and the encapsulation layer 23 are sequentially stacked on one another. In some embodiments, the connection defining layer 41 may be arranged in the same layer as the pixel defining layer. The connection defining layer 41 and the pixel defining layer may be produced in the same patterning process. The second conductive insolation structure 50 may be arranged in the same layer as the first conductive insolation structure 24 and may be connected to the first conductive insolation structure 24. The second conductive insolation structure 50 and the first conductive insolation structure 24 may be produced in the same process. The second conductive insolation structure 50, by arranging in the same layer as the first conductive insolation structure 24 and being connected to the first conductive insolation structure 24, may be enabled to be electrically coupled to the cathodes in the display region 101.

In some embodiments, the connection defining layer 41 may be disposed on a side of the connecting electrode 12 away from the driving substrate 10. The connection defining layer 41 may define a plurality of connecting openings 411. The plurality of connecting openings 411 may be configured to expose the connecting electrode 12. The second conductive insolation structure 50 may protrude out of the connection defining layer 41. The second conductive insolation structure 50 may be in the shape of a mesh or a grid to enclose or define a plurality of encapsulation openings 511. It may be understood that, similar to the design of the pixel openings 212 in the display region 101, the second conductive insolation structure 50 may be in the shape of a mesh and protrude out of the connection defining layer 41. The second conductive insolation structure 50 in the shape of a mesh encloses or defines the plurality of encapsulation openings 511.

Further, an orthographic projection of each connecting opening 411 onto the driving substrate 10 may be located within an orthographic projection of the second conductive insolation structure 50 onto the driving substrate 10, and the second conductive insolation structure 50 may contact and be electrically or conductively connected to the connecting electrode 12 through the connecting openings 411. Besides, the second conductive insolation structure 50 may be connected to the first conductive insolation structure 24 in the display region 101 to form an electrically coupled connection. The first conductive insolation structure 24 may be electrically coupled to the cathodes, such that the cathodes may be electrically coupled to the connecting electrode 12 through the first conductive insolation structure 24 and the second conductive insolation structure 50. In this way, the cathodes may be electrically coupled to the connecting electrode 12, and the connecting electrode 12 may be electrically coupled to the power line 11 in the driving substrate 10. Therefore, the cathodes may be electrically coupled to and enabled to achieve signal connectivity to the power line 11 through the first conductive insolation structure 24, the second conductive insolation structure 50, and the connecting electrode 12, and a voltage drop between the second conductive insolation structure 50 and the connecting electrode 12 may be reduced.

In some embodiments, in the process of manufacturing the light emitting layer 25 and the cathode 26 in the display region 101, since the light emitting layer 25 and the cathode 26 are formed on the corresponding substrates by scanning and depositing an evaporation source on a master, the light emitting layer 25 and the cathode 26 may be also deposited in the encapsulation openings 511 formed by the second conductive insolation structure 50 located in the border region 102. Accordingly, within the each encapsulation opening 511, the light emitting layer 25 and the cathode 26 may be also stacked between the connection defining layer 41 and the encapsulation layer 23. In some embodiments, the cathode 26 may be located within the each encapsulation opening 511, extend to the second conductive insolation structure 50, and further contact and be electrically or conductively connected to the second conductive insolation structure 50. In this way, it is possible to further reduce an impedance of the cathode 26. The cathode 26 may further be electrically coupled to the connecting electrode 12 via the second conductive insolation structure 50.

In some embodiments, with reference to FIG. 2, the driving substrate 10 may further include the power line 11 disposed in the border region 102. The power line 11 may be at least partially overlapped with the connecting electrode 12 in the direction substantially perpendicular to the driving substrate 10. In the overlapping region, the connecting electrode 12 may be electrically connected to the power line 11 through a connecting through-hole, so as to achieve a coupling of the cathode to the power signal.

In some embodiments, the encapsulation layer 23 may include at least the organic encapsulation layer 232. In the display region 101, the organic encapsulation layer 232 may be disposed on a side of the first conductive insolation structure 24 away from the driving substrate 10. The organic encapsulation layer 232 may be filled in the pixel openings 212 to encapsulate the corresponding sub-pixel units 30. In this way, it is possible to reduce the failure of the sub-pixel units 30 caused by invasion of external water and oxygen. The organic encapsulation layer 232 may extend to the signal connection region 1021 in a direction substantially parallel to the driving substrate 10. In the signal connection region 1021, the organic encapsulation layer 232 may be filled in the encapsulation openings 511 and continue to extend to a side of the isolation dam region 1022 that is near or close to the signal connection region 1021 in the direction away from the display region 101.

It may be easily understood that, since the second conductive insolation structure 50 in the signal connection region 1021 is in the shape of a mesh and defines the plurality of encapsulation openings 511, a plurality of protrusions and a plurality of recesses may be formed in the signal connection region 1021, and thus, the second conductive insolation structure 50 may offer a blocking effect on the organic encapsulation layer 232. In this way, the leveling distance of the organic encapsulation layer 232 between the signal connection region 1021 and the isolation dam region 1022 may be reduced, the safety distance D between the signal connection region 1021 and the isolation dam region 1022 may be reduced, and the width of the border of the display panel 100 may be effectively reduced.

In some embodiments, at least one dam 60 may be disposed in the isolation dam region 1022. The at least one dam 60 may be configured to block the organic encapsulation layer 232, confine or limit the organic encapsulation layer 232 within a region enclosed or surrounded by the isolation dam region 1022, and reduce the risk of overflow of the material forming the organic encapsulation layer 232, so as to ensure the effectiveness of encapsulation of the organic encapsulation framework (Thin Film Encapsulation, TFE), and thus ensure the reliability of the product.

In some embodiments, in the direction substantially perpendicular to the display panel 100, the second conductive insolation structure 50 may include a conductive blocking structure (also called as “conductive enclosure structure”) 51 and a top structure 52 stacked on one another. In some embodiments, the conductive blocking structure 51 may be disposed on a side of the connection defining layer 41 away from the driving substrate 10. The conductive blocking structure 51 may protrude out of the connection defining layer 41. An orthographic projection of the conductive blocking structure 51 onto the driving substrate 10 may be in the shape of a mesh, such that the conductive blocking structure 51 may define a plurality of opening structures, i.e., the plurality of encapsulation openings 511. The conductive blocking structure 51 may offer a blocking effect on the organic encapsulation layer 232, such that the leveling distance of the organic encapsulation layer 232 may be shortened, thereby reducing the width of the border region 102, which may be conducive to the design of a narrow border.

The conductive blocking structure 51 may cover each of the plurality of connecting openings 411 in the direction substantially perpendicular to the driving substrate 10, i.e., the conductive blocking structure 51 may be disposed above the connecting openings 411 and filled into the connecting opening 411 (that is, a part of the conductive blocking structure 51 may be filled in each of the plurality of connecting openings 411, and the conductive blocking structure 51 may further protrude out of the each of the plurality of connecting openings 411). In this way, the conductive blocking structure 51 may contact and be electrically or conductively connected to the connecting electrode 12 through the connecting openings 411. Besides, the conductive blocking structure 51 and the conductive structure 221 of the first conductive insolation structure 24 may be arranged in the same layer, such that the conductive blocking structure 51 may be electrically coupled to the cathodes through the first conductive insolation structure 24. In this way, the cathodes may be electrically coupled to the connecting electrode 12, so as to achieve a signal connection between the cathodes and the power line 11.

The top structure 52 may be arranged on an upper surface of the conductive blocking structure 51 on a side away from the driving substrate 10. The top structure 52 may cover the conductive blocking structure 51; i.e., the orthographic projection of the conductive blocking structure 51 onto the driving substrate 10 may be located within an orthographic projection of the top structure 52. The top structure 52 may further extend out of or extend beyond the conductive blocking structure 51 in a direction substantially parallel to the connection defining layer 41, such that an overhanging structure may be formed, which may further block the organic encapsulation layer 232. In this way, the blocking effect to the organic encapsulation layer 232 may be further improved, the leveling distance of the organic encapsulation layer 232 may be further shortened, and the width of the border region 102 may be further reduced.

In some embodiments, the driving substrate 10 may include a substrate 13 and a driving layer 14. The driving layer 14 may be disposed on the substrate 13. The driving layer 14 may include a pixel driving circuit (not shown in the figures) and the power line 11. In some embodiments, the substrate 13 may be an optical-grade glass substrate or a flexible substrate. The flexible substrate may be a substrate made of a polyimide (PI) material. In the driving layer 14, a pixel driving circuit may be located in the display region 101, electrically connected to the anode of the corresponding sub-pixel unit 30, and configured to drive the sub-pixel to emit light. The power line 11 may be disposed in the border region 102 and surround the display region 101. The power line 11 may be disposed in the same layer as a first metal layer (gate layer) or a second metal layer (source-drain layer) in the pixel driving circuit.

In some embodiments, as shown in FIG. 6, an open area of each encapsulation opening 511 in the signal connection region 1021 may be not less than (i.e., greater than or equal to) half of an open area of any pixel opening 212 in the display region 101. It may be understood that, the open area of each encapsulation opening 511 may be at least half of the open area of any pixel opening 212 in the display region 101, such that a difference between a capacity of each encapsulation opening 511 for receiving the organic encapsulation material and a capacity of each pixel opening 212 in the display region 101 for receiving the organic encapsulation material may be small, and thus it is possible to ensure that the arrangement or coating of the organic encapsulation layer 232 in the signal connection region 1021 is substantially consistent with the arrangement effect of the organic encapsulation layer 232 in the display region 101, and the arrangement or coating of the organic encapsulation layer 232 in the display region 101 and the signal connection region 1021 may be more uniformed. Besides, through the above-described arrangement of the opening size of the encapsulation opening 511, it may be also possible to further enhance the blocking effect of the second conductive insolation structure 50 on the organic encapsulation layer 232, which in turn further reduces the leveling distance of the organic encapsulation layer 232, and shortens the safety distance D between the signal connection region 1021 and the isolation dam region 1022, thereby further reducing the width of the border.

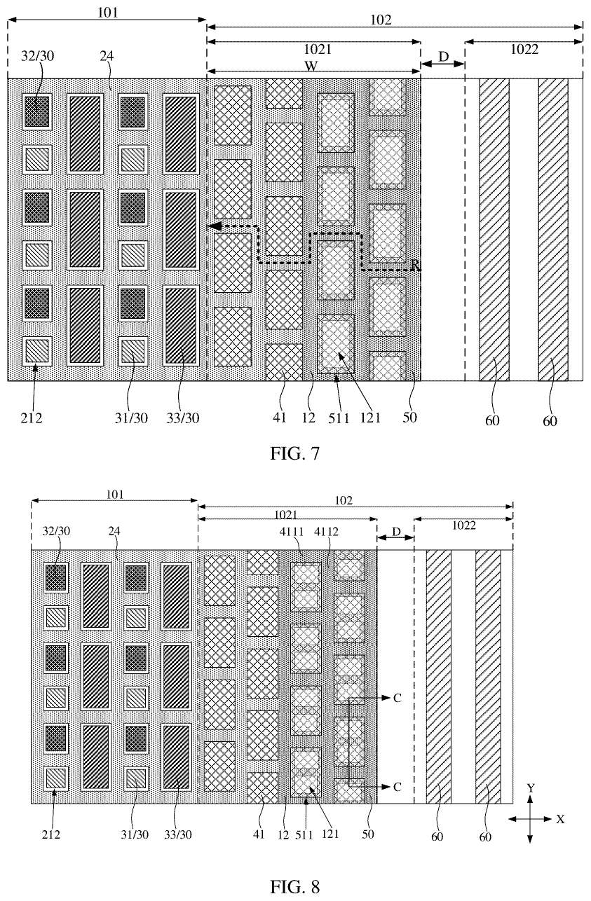

As shown in FIG. 4 and FIG. 7, FIG. 7 is a schematic planar view of a display panel provided in some embodiments of the present disclosure. The configuration of the display panel shown in FIG. 7 is substantially the same as the configuration of the display panel shown in FIG. 4. The different lines in that, in some embodiments as shown in FIG. 7, in the signal connection region 1021, the plurality of encapsulation openings 511 may be disposed around the display region 101 along a peripheral direction of the display region 101. Besides, the plurality of encapsulation openings 511 may be arranged in a plurality of rows in the direction away from the display region 101. It may be understood that, the plurality of encapsulation openings 511 may be arranged in a plurality of circles around the display region 101 along the peripheral direction of the display region 101, so as to block the organic encapsulation layer 232 at the periphery of the display region 101.

In some embodiments, due to the above-described arrangement of the second conductive insolation structure 50, the external water and oxygen may be invaded into the display region 101 via a gap or space between the top structure 52 of the second conductive insolation structure 50 and the encapsulation layer 23. Therefore, in case that the mesh structure of the second conductive insolation structure 50 is a linear structure in the direction away from the display region 101, i.e., in case that the second conductive insolation structure 50 is a horizontal-vertical mesh structure, an invasion path R of the external water and oxygen will be straight. Due to the design of the narrow border, the invasion path R of the water and oxygen will be shortened, which may be not favorable to the reliability of the encapsulation.

To solve the above technical problem, in some embodiments, in the direction away from the display region 101, for the multiple rows of the encapsulation openings 511, the encapsulation openings in each row may be staggered with or misaligned with the encapsulation openings 511 in adjacent rows, such that the second conductive insolation structure 50 may have a folded-line structure in the direction away from the display region 101, and may no longer have a straight-line structure. In this case, the invasion path R of the external water and oxygen in the signal connection region 1021 may be also a folded-line path and the external water and oxygen cannot be invaded in a straight line. In this way, the length of the invasion path R of the external water and oxygen in the signal connection region 1021 may be greater than the width W of the signal connection region 1021, the length of the invasion path R of the water and oxygen may be effectively increased, and the encapsulation reliability of the encapsulation layer 23 may be effectively enhanced. It is to be noted that, the width W of the signal connection region 1021 involved in some embodiments of the present disclosure may refer to the width W of the signal connection region 1021 in the direction away from the display region 101.

In some embodiments, each encapsulation opening 511 may be in the shape of a rectangle, a circle, a polygon, or in other irregular shapes, which may be set as desired. In some embodiments, the shape and the opening size of each encapsulation opening 511 may be designed, to design the invasion path R of the water and oxygen. It is possible to appropriately increase the length of the invasion path R of the external water and oxygen in the signal connection region 1021, such that the length of the invasion path R may be greater than or equal to twice the width W of the signal connection region 1021, so as to effectively enhance the encapsulation reliability of the encapsulation layer 23.

In some embodiments, as shown in FIG. 7, the connecting electrode 12 may have a plurality of hollow portions 121, such that the connecting electrode 12 may be formed into a mesh structure. In some embodiments, an orthographic projection of each hollow portion 121 onto the driving substrate 10 may be disposed within an orthographic projection of the corresponding encapsulation opening 511 onto the driving substrate 10. The plurality of hollow portions 121 may be in one-to-one correspondence with the plurality of encapsulation openings 511. An area of each hollow portion 121 may be slightly less than an open area of the corresponding encapsulation opening 511, such that a material of the connecting electrode 12 may be reduced. Besides, the connecting electrode 12 may be permeable, which may facilitate the circuit design of the driving layer 14.

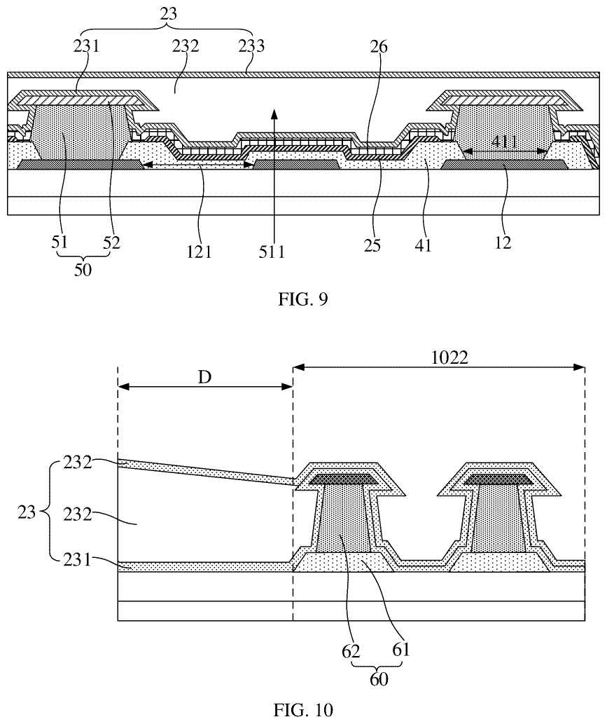

As shown in FIGS. 8 and 9, FIG. 8 is a schematic planar view of a display panel provided in some embodiments of the present disclosure, and FIG. 9 is a schematic cross-sectional view of the display panel in a C-C orientation in some embodiments shown in FIG. 8. The configuration of the display panel shown in FIG. 8 is substantially the same as the configuration of the display panel shown in FIG. 7. The different lines in that, in the display panel 100 provided in some embodiments shown in FIGS. 8-9, in the signal connection region 1021, the connecting electrode 12 may have a plurality of hollow portions 121. The area of each hollow portion 121 may be less than the area of the corresponding encapsulation opening 511, and the orthographic projection of each encapsulation opening 511 onto the driving substrate 10 may cover the orthographic projection of each of at least one of the hollow portions 121 onto the driving substrate 10. That is, in the direction substantially perpendicular to the driving substrate 10, each encapsulation opening 511 may be disposed above the corresponding hollow portion 121 and may cover at least one hollow portion 121. In other words, the encapsulation openings 511 may be in one-to-one or one-to-many correspondence with the hollow portions 121. In some embodiments, it may be understood that, in the signal connection region 1021, each encapsulation opening 511 may enclose or surround at least one hollow portion 121 in the direction substantially parallel to the driving substrate 10; i.e., each encapsulation opening 511 may enclose one or more hollow portions 121. By arranging the encapsulation openings 511 to enclose the plurality of hollow portions 121, the area of each hollow portion 121 may decrease, which may increase the laying or extension area of the connecting electrode 12 and effectively reduce the impedance of the connecting electrode 12. In this way, it is possible to reduce the heat generated by the connecting electrode 12 and reduce the occurrence of the signal voltage drop.

In some embodiments, in the signal connection region 1021, the orthographic projection of each encapsulation opening 511 onto the driving substrate 10 may cover orthographic projections of two to four hollow portions 121 onto the driving substrate 10, so as to effectively reduce the impedance of the connecting electrode 12. For example, in some embodiments, the orthographic projection of each encapsulation opening 511 onto the driving substrate 10 may cover two hollow portions 121, i.e., each encapsulation opening 511 may surround two hollow portions 121 in the direction substantially parallel to the driving substrate 10, so as to reduce the impedance of the connecting electrode 12 and reduce the heat generated by the connecting electrode 12.

In some embodiments, the connecting electrode 12 and the anodes of the sub-pixel units 30 in the display region 101 may be disposed in the same layer. That is, the connecting electrode 12 and the anodes may be produced in the same patterning process. In some embodiments, the connection defining layer 41 and the pixel defining layer 21 may be disposed in the same layer. The connection defining layer 41 and the pixel defining layer 21 may be produced after the production of the connecting electrode 12 and the anodes. The connection defining layer 41 and the pixel defining layer of a preset shape may be formed by a patterning process to facilitate the production without needing an extra producing operation.

In some embodiments of the present disclosure, as shown in FIGS. 5 and 8, the connecting openings 411 defined by the connection defining layer 41 may include a first opening 4111 extending along a first direction X and a second opening 4112 extending along a second direction Y. The first opening 4111 and the second opening 4112 may be fluidly connected to each other to form a connecting channel 410, and the connecting channel 410 may be in the shape of a mesh. The connecting channel 410 may be configured to expose the connecting electrode 12. The second conductive insolation structure 50 may be arranged in the connecting channel 410, and contact and be electrically or conductively connected to the connecting electrode 12 through the connecting channel 410. In some embodiments, the first direction X may intersect with the second direction Y. In some embodiments, taking the horizontal direction as the first direction X and the vertical direction as the second direction Y as an example, on the connection defining layer 41, the connecting channel 410 may be arranged below the second conductive insolation structure 50 to expose the connecting electrode 12. In this way, the second conductive insolation structure 50 may contact and be electrically or conductively connected to the connecting electrode 12 through the connecting channel 410. In some embodiments, the connecting channel 410 may include the first opening 4111 in the horizontal direction and the second opening 4112 in the vertical direction. The first opening 4111 may intersect with and be fluidly connected to the second opening 4112, such that a mesh the same as the second conductive insolation structure 50 may be formed. In this way, the contact area between the second conductive insolation structure 50 and the connecting electrode 12 may be enlarged, which makes the electric current signals more dispersed. Therefore, it is possible to reduce the damage to the connecting structure caused by a greater amount of heat, and the electrical connection between the second conductive insolation structure 50 and the connecting electrode 12 may be more reliable.

Of course, in other embodiments, each connecting opening 411 may also be a through-hole. The connection defining layer 41 may define a plurality of disconnected through-holes under the second conductive insolation structure 50, so as to expose the connecting electrode 12. In this way, the second conductive insolation structure 50 may contact and be conductively connected to the connecting electrode 12 through the connecting openings 411 in the form of through-holes to form an electrical connection.

As shown in FIGS. 8 and 10, FIG. 10 is a schematic cross-sectional view of an isolation dam region provided by some embodiments of the present disclosure. In some embodiments of the present disclosure, two dams 60 spaced apart from each other may be disposed in the isolation dam region 1022. The two dams 60 may be disposed sequentially in the direction away from the display region 101. The dams 60 may be configured to block the organic encapsulation layer 232. In this way, the organic encapsulation layer 232 may be confined or limited to a side of the isolation dam region 1022 close to the display region 101, and the encapsulation effectiveness may be ensured.

In some embodiments, in the direction substantially perpendicular to the display panel 100, each dam 60 may include a dam base 61 and a third conductive insolation structure 62 stacked on one another. In some embodiments, the dam base 61 may be disposed in the same layer as the pixel defining layer 21 and the connection defining layer 41, i.e., the dam base 61, the pixel defining layer 21, and the connection defining layer 41 may be produced in the same producing process to reduce the producing operation. The third conductive insolation structure 62 disposed on the dam base 61 may be disposed in the same layer as the first conductive insolation structure 24 and the second conductive insolation structure 50. The third conductive insolation structure 62, the first conductive insolation structure 24, and the second conductive insolation structure 50 may be produced in the same manufacturing process to reduce the producing operation. In some embodiments, during the process of producing the conductive insolation structure, the third conductive insolation structure 62 may be also formed on the dam base 61. In this way, the height of the dam 60 in the direction substantially perpendicular to the display panel 100 may be effectively increased, and the blocking effect of the dam 60 on the organic encapsulation layer 232 may be improved.

In some embodiments, the encapsulation layer 23 may include a first inorganic encapsulation layer 231, the organic encapsulation layer 232, and a second inorganic encapsulation layer 233 that are sequentially stacked on one another. The organic encapsulation layer 232 may cover the display region 101 and the signal connection region 1021. The organic encapsulation layer 232 may extend in a direction close to the isolation dam region 1022 for an extension distance that does not exceed (i.e., not greater than) the safety distance D. The first inorganic encapsulation layer 231 and the second inorganic encapsulation layer 233 may cover the display region 101 and the border region 102. In the isolation dam region 1022, the first inorganic encapsulation layer 231 may be partially overlapped with and in contact with the second inorganic encapsulation layer 233 in the direction substantially perpendicular to the display panel 100, i.e., edges of the first inorganic encapsulation layer 231 and the second inorganic encapsulation layer 233 may extend beyond the organic encapsulation layer 232. In this way, the organic encapsulation layer 232 may be encapsulated or wrapped between the first inorganic encapsulation layer 231 and the second inorganic encapsulation layer 233. Thus, it is possible to reduce the occurrence of the invasion of the external water and oxygen into the display region 101 from space between the organic encapsulation layer 232 and the inorganic encapsulation layers 231 and 233, so as to ensure the effectiveness of the organic encapsulation frame (TFE) and ensure the reliability of the product.

It should be noted that, since the light emitting layer 25 and the cathode 26 are deposited on the substrate by scanning and evaporating an evaporation source in a direction substantially parallel to the display panel 100, the light emitting layer 25 and the cathode 26 may be also deposited in a region corresponding to the safety distance D and in the isolation dam region 1022 (not shown in the figures). In the region within the safety distance D, the light emitting layer 25 and the cathode 26 may be located between the driving substrate 10 and the first inorganic encapsulation layer 231. The cathode 26 may extend to the third conductive insolation structure 62 where the cathode 26 contacts and is conductively connected to the third conductive insolation structure 62. In the isolation dam region 1022, the light emitting layer 25 and the cathode 26 may be located in a recess formed between the two dams 60, and located between the driving substrate 10 and the first inorganic encapsulation layer 231. The cathode 26 may further extend to the third conductive insolation structure 62, where the cathode 26 contacts and is conductively connected to the third conductive insolation structure 62. In this way, it is possible to further reduce the impedance, and to facilitate the signal connection between the cathode 26 and a peripheral signal wiring. Of course, it may be also possible to remove the light-emitting layer 25 and the cathode 26 in the region within the safety distance D and within the isolation dam region 1022 before the encapsulation layer 23 is arranged. The removal may be achieved, for example, by etching. After that, the encapsulation layer 23 is arranged. The formation sequence may be set according to actual needs, which is not limited herein.

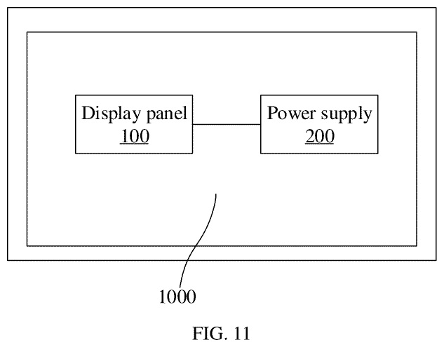

FIG. 11 is a schematic structural view of a display device provided by some embodiments of the present disclosure. In some embodiments, a display device 1000 may be provided. The display device 1000 may be configured in fields such as tablets, mobile phones, in-vehicle displays, lighting, and other fields.

The display device 1000 may include a display panel 100 and a power supply 200. The power supply 200 may be configured to supply power to the display panel 100. The structure and function of the display panel 10 are the same as or similar to those of the display panel 100 in the above embodiments, and the same technical effects may be achieved. For details, reference may be made to the above detailed description, which will not be repeated here.

The display panel 100 in the display device 1000 may adopt the display panel 100 in the above embodiments, which may improve the reliability of the electrical connection between the cathode and the connecting electrode 12. Besides, the width of the border may be effectively shortened, the length of the invasion path R for the external water and oxygen may be increased, and the reliability of the package may be improved.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, having a display region and a border region located around the display region, the border region comprising a signal connection region and an isolation dam region disposed sequentially in a direction away from the display region; the signal connection region being at a safety distance from the isolation dam region;
wherein in a direction substantially perpendicular to the display panel, the signal connection region comprises a driving substrate, a connecting electrode, a connection defining layer, a first conductive insolation structure, and an encapsulation layer sequentially stacked on one another; wherein the first conductive insolation structure is electrically coupled to a cathode in the display region, the connecting electrode is electrically coupled to a power line in the driving substrate, and the encapsulation layer comprises an organic encapsulation layer;
wherein the first conductive insolation structure protrudes from the connection defining layer, is in the shape of a mesh, and defines a plurality of encapsulation openings; the connection defining layer defines a plurality of connecting openings, the plurality of connecting openings are configured to expose the connecting electrode; an orthographic projection of each of the plurality of connecting openings onto the driving substrate is located within an orthographic projection of the first conductive insolation structure onto the driving substrate, the first conductive insolation structure contacts and is conductively connected with the connecting electrode, and the organic encapsulation layer is filled in the plurality of encapsulation openings and covers the first conductive insolation structure.

2. The display panel as claimed in claim 1, wherein in the direction substantially perpendicular to the display panel, the first conductive insolation structure comprises a conductive blocking structure and a top structure stacked on one another;
the conductive blocking structure is disposed on a side of the connection defining layer away from the driving substrate, an orthographic projection of the conductive blocking structure onto the driving substrate is in the shape of a mesh to define the plurality of encapsulation openings; in the direction substantially perpendicular to the driving substrate, the conductive blocking structure covers the plurality of connecting openings, such that the conductive blocking structure contacts and is conductively connected with the connecting electrode through the plurality of connecting openings; and
wherein the top structure is arranged on a surface of the conductive blocking structure away from the driving substrate, covers the conductive blocking structure, and extends beyond the conductive blocking structure in a direction substantially parallel to the connection defining layer; and
wherein the plurality of encapsulation openings are configured to expose the connection defining layer.

3. The display panel as claimed in claim 2, wherein the pixel defining layer defines a plurality of pixel openings, the plurality of pixel openings are arranged in an array, and a sub-pixel unit is arranged in each of the plurality of pixel openings;
wherein an open area of each of the plurality of encapsulation openings is equal to or greater than half of an open area of any one of the pixel openings.

4. The display panel as claimed in claim 2, wherein the plurality of encapsulation openings are arranged in a plurality of rows in the direction away from the display region, and the encapsulation openings in each row are staggered with the encapsulation openings in adjacent rows.

5. The display panel as claimed in claim 2, wherein the connecting electrode has a plurality of hollow portions, an area of each of the plurality of hollow portions is less than an open area of any one of the plurality of encapsulation openings, and an orthographic projection of each of the plurality of encapsulation openings onto the driving substrate covers an orthographic projection of at least one of the plurality of hollow portions onto the driving substrate.

6. The display panel as claimed in claim 5, wherein the orthographic projection of each of the plurality of encapsulation openings onto the driving substrate covers orthographic projections of two to four hollow portions onto the driving substrate.

7. The display panel as claimed in claim 1, wherein the connecting openings comprises a first opening extending along a first direction and a second opening extending along a second direction, the first opening and the second opening are fluidly connected to each other to form a mesh-like connection channel, and the connecting channel is configured to expose the connecting electrode;
wherein the first conductive insolation structure is arranged in the connecting channel, contacts the connecting electrode through the connecting channel, and is further conductively connected to the connecting electrode through the connecting channel; and
wherein the first direction intersects with the second direction.

8. The display panel as claimed in claim 1, wherein the connecting electrode is arranged on the same layer as an anode in the display region.

9. The display panel as claimed in claim 1, wherein two dams spaced apart from each other are disposed in the isolation dam region, and the two dams are disposed sequentially in the direction away from the display region;
in the direction substantially perpendicular to the display panel, each of the two dams comprises a dam base and a second conductive insolation structure stacked on one another, and the each of the two dams is configured to block the organic encapsulation layer; and
wherein the encapsulation layer comprises a first inorganic encapsulation layer, the organic encapsulation layer, and a second inorganic encapsulation layer; the organic encapsulation layer covers the display region and the signal connection region, and further extends in a direction close to the isolation dam region for an extension distance less than or equal to the safety distance; the first inorganic encapsulation layer and the second inorganic encapsulation layer covers the display region and the border region; and
wherein in the isolation dam region, the first inorganic encapsulation layer is overlapped with and in contact with the second inorganic encapsulation layer.

10. The display panel as claimed in claim 1, wherein a pixel defining layer is arranged in the display region, the pixel defining layer is in the shape of a mesh and defines a plurality of pixel openings, and each of the plurality of pixel openings has a sub-pixel unit arranged therein;
a third conductive insolation structure protrudes from the pixel defining layer and defines a plurality of cathode openings, the plurality of cathode openings and the plurality of pixel openings are in a one-to-one correspondence, and an orthographic projection of each of the plurality of pixel openings onto the driving substrate is located within an orthographic projection of a corresponding one of the cathode openings onto the driving substrate.

11. The display panel as claimed in claim 10, wherein the connection defining layer is arranged in the same layer as the pixel defining layer, the first conductive insolation structure is electrically connected to the third conductive insolation structure, and the third conductive insolation structure is further electrically connected to the cathode.

12. The display panel as claimed in claim 1, wherein the light emitting layer and the cathode are stacked between the connection defining layer and the encapsulation layer, the cathode is located within each of the plurality of encapsulation openings, extends to the first conductive insolation structure, and further contacts and is electrically connected to the first conductive insolation structure.

13. A display device, comprising:
a display panel, having a display region and a border region located around the display region, the border region comprising a signal connection region and an isolation dam region disposed sequentially in a direction away from the display region; the signal connection region being at a safety distance from the isolation dam region;
wherein in a direction substantially perpendicular to the display panel, the signal connection region comprises a driving substrate, a connecting electrode, a connection defining layer, a first conductive insolation structure, and an encapsulation layer sequentially stacked on one another; wherein the first conductive insolation structure is electrically coupled to a cathode in the display region, the connecting electrode is electrically coupled to a power line in the driving substrate, and the encapsulation layer comprises an organic encapsulation layer;
wherein the first conductive insolation structure protrudes from the connection defining layer, is in the shape of a mesh, and defines a plurality of encapsulation openings; the connection defining layer defines a plurality of connecting openings, the plurality of connecting openings are configured to expose the connecting electrode; an orthographic projection of each of the plurality of connecting openings onto the driving substrate is located within an orthographic projection of the first conductive insolation structure onto the driving substrate, the first conductive insolation structure contacts and is conductively connected with the connecting electrode, and the organic encapsulation layer is filled in the encapsulation openings and covers the first conductive insolation structure; and
a power supply, configured to supply power to the display panel.

14. The display device as claimed in claim 13, wherein in the direction substantially perpendicular to the display panel, the first conductive insolation structure comprises a conductive blocking structure and a top structure stacked on one another;
the conductive blocking structure is disposed on a side of the connection defining layer away from the driving substrate, an orthographic projection of the conductive blocking structure onto the driving substrate is in the shape of a mesh to define the plurality of encapsulation openings; in the direction substantially perpendicular to the driving substrate, the conductive blocking structure covers the plurality of connecting openings, such that the conductive blocking structure contacts and is conductively connected with the connecting electrode through the plurality of connecting openings; and
wherein the top structure is arranged on a surface of the conductive blocking structure away from the driving substrate, covers the conductive blocking structure, and extends beyond the conductive blocking structure in a direction substantially parallel to the connection defining layer; and
wherein the plurality of encapsulation openings are configured to expose the connection defining layer.

15. The display device as claimed in claim 14, wherein the pixel defining layer defines a plurality of pixel openings, the plurality of pixel openings are arranged in an array, and a sub-pixel unit is arranged in each of the plurality of pixel openings;
wherein an open area of each of the plurality of encapsulation openings is equal to or greater than half of an open area of any one of the pixel openings.

16. The display device as claimed in claim 14, wherein the plurality of encapsulation openings are arranged in a plurality of rows in the direction away from the display region, and the encapsulation openings in each row are staggered with the encapsulation openings in adjacent rows.

17. The display device as claimed in claim 14, wherein the connecting electrode has a plurality of hollow portions, an area of each of the plurality of hollow portions is less than an open area of any one of the plurality of encapsulation openings, and an orthographic projection of each of the plurality of encapsulation openings onto the driving substrate covers an orthographic projection of at least one of the plurality of hollow portions onto the driving substrate.

18. The display device as claimed in claim 13, wherein the connecting openings comprises a first opening extending along a first direction and a second opening extending along a second direction, the first opening and the second opening are fluidly connected to each other to form a mesh-like connection channel, and the connecting channel is configured to expose the connecting electrode;
wherein the first conductive insolation structure is arranged in the connecting channel, contacts the connecting electrode through the connecting channel, and is further conductively connected to the connecting electrode through the connecting channel; and
wherein the first direction intersects with the second direction.

19. The display device as claimed in claim 13, wherein two dams spaced apart from each other are disposed in the isolation dam region, and the two dams are disposed sequentially in the direction away from the display region;
in the direction substantially perpendicular to the display panel, each of the two dams comprises a dam base and a second conductive insolation structure stacked on one another, and the each of the two dams is configured to block the organic encapsulation layer; and
wherein the encapsulation layer comprises a first inorganic encapsulation layer, the organic encapsulation layer, and a second inorganic encapsulation layer; the organic encapsulation layer covers the display region and the signal connection region, and further extends in a direction close to the isolation dam region for an extension distance less than or equal to the safety distance; the first inorganic encapsulation layer and the second inorganic encapsulation layer covers the display region and the border region; and
wherein in the isolation dam region, the first inorganic encapsulation layer is overlapped with and in contact with the second inorganic encapsulation layer.

20. A display panel, having a display region and a border region located around the display region, the border region comprising a signal connection region and an isolation dam region disposed sequentially in a direction away from the display region; the signal connection region being at a safety distance from the isolation dam region;
wherein in a direction substantially perpendicular to the display panel, the signal connection region comprises a driving substrate, a connecting electrode, a connection defining layer, a conductive insolation structure, and an encapsulation layer sequentially stacked on one another; wherein the conductive insolation structure is electrically coupled to a cathode in the display region, the connecting electrode is electrically coupled to a power line in the driving substrate, and the encapsulation layer comprises an organic encapsulation layer;
wherein the connection defining layer is in the shape of a grid and defines a plurality of connecting openings, the plurality of connecting openings are configured to expose the connecting electrode;
wherein an end of the conductive insolation structure is received in the plurality of connecting openings and is electrically connected to the connecting electrode, another end of the conductive insolation structure protrudes out of the plurality of connecting openings such that the conductive insolation structure is formed into a grid with a plurality of encapsulation openings; and
wherein the organic encapsulation layer is filled in the encapsulation openings, and the conductive insolation structure is configured to block the organic encapsulation layer.
